(19) United States
(12) Patent Application Publication
(10) Pub. No.: US 2026/0052912 A1
(43) Pub. Date: Feb. 19, 2026

(54) DEVICES AND METHODS FOR TERMINATING TRANSMISSION LINES

(71) Applicant: Sandisk Technologies, Inc., Milpitas, CA (US)

(72) Inventor: Daniel BEDAU, San Jose, CA (US)

(73) Assignee: Sandisk Technologies, Inc., Milpitas, CA (US)

(21) Appl. No.: 18/805,352

(22) Filed: Aug. 14, 2024

(51) Int. Cl. H10N 70/00; H10B 61/00; H10B 63/00; H10B 63/10

(52) U.S. Cl. CPC H10N 70/8833; H10B 63/10; H10B 63/24; H10N 70/882; H10B 61/10

(57) ABSTRACT

Disclosed are termination line termination circuits and methods of terminating transmission lines. A transmission line termination circuit for terminating a transmission line may include a termination impedance and a threshold switching device. The threshold switching device may include a first terminal coupled to a first conductor of the transmission line, a second terminal coupled to a second conductor of the transmission line, and an active layer situated between the first terminal and the second terminal. The active layer comprises a switching material configured to be in a substantially conductive state in response to a voltage on the transmission line being in a range above a threshold voltage and in a substantially non-conductive state in response to the voltage on the transmission line being in a range below the threshold voltage.

### BACKGROUND

Terminating an electrical transmission line properly is important to ensure signal integrity and to prevent degradations. If the end of a transmission line is not properly terminated, the signal can be partially or fully reflected by the end of the line, which can cause standing waves and signal distortion.

The simplest and most common approach to line termination is to use resistive termination to attempt to match the impedance of the line. Resistive termination involves placing a resistor with a resistance value equal to the characteristic impedance of the line at the end of the transmission line.

Although resistive termination is simple and inexpensive, it has several drawbacks. For example, resistive termination results in power dissipation within the resistor, which can lead to heating, especially at higher frequencies or power levels. Another drawback is that the terminating resistor absorbs part of the signal power, leading to signal attenuation, which can be problematic in some applications (e.g., where signal strength is critical, such as in long-distance communication or low-power devices).

Another drawback of resistive termination is that a resistor can introduce thermal noise, which can degrade the signal-to-noise ratio (SNR) of the system. The effects of SNR degradation can be especially problematic in high-frequency or sensitive analog signal applications. Resistive termination can also affect the signal integrity in high-speed circuits. The rise and fall times of signal edges can be affected, which can increase jitter, reduce signal quality, increase noise, and/or increase distortion. Resistive termination solutions can also be physically large, which can increase the cost and size of a printed circuit board (PCB).

It can also be challenging to achieve a perfect resistive match because of variations in the characteristic impedance of the transmission line and/or the tolerance of the terminating resistor. Because a resistor has a roughly flat frequency response, resistive termination may provide good matching at some frequencies but might be suboptimal at others. One way to address the frequency-agnostic matching provided by a purely-resistive termination approach is to use a combination of passive components (resistors, capacitors, and/or inductors) to create a circuit with a complex impedance that matches the characteristic impedance of the transmission line at a specific frequency or over range of frequencies. Although this type of approach can better match the characteristic impedance, it is also more expensive and complicated than resistive termination, and it can also increase the cost and size of a PCB. In some applications, there may be insufficient space available for such a circuit.

Active termination is an alternative to passive termination. As its name suggests, active termination uses active components, such as diodes, transistors, or operational amplifiers, to provide dynamic impedance matching that can adapt to varying signal conditions.

Although active termination can provide better performance than passive termination, conventional approaches also have several disadvantages. Active termination circuits are larger and more expensive than passive termination approaches. Active components also require a power supply to operate, which leads to higher power consumption compared to passive terminations. In addition, active termination circuits are more complex to design and implement as compared to passive termination approaches. The use of active components can make troubleshooting and maintenance more challenging. And, as is known to those in the art, active components have a higher likelihood of failure than passive components, which can affect the reliability of the entire system.

In addition, active components can introduce additional noise into the system. Active termination circuits can become unstable over time, leading to oscillations and signal degradation, especially if the termination is to be provided over a wide range of frequencies and/or temperatures. Active components can also be sensitive to temperature changes, which can affect their performance and potentially lead to mismatches in impedance if not properly compensated. The dynamic range of an active termination circuit may also be limited, making such termination approaches less suitable for signals with large amplitude variations.

There is, therefore, a need for improved techniques for terminating transmission lines.

### SUMMARY

This summary represents non-limiting embodiments of the disclosure.

In some aspects, the techniques described herein relate to a transmission line termination circuit for terminating a transmission line, the transmission line termination circuit including a threshold switching device. The threshold switching device includes a first terminal to be coupled to a first conductor of the transmission line, a second terminal to be coupled to a second conductor of the transmission line, and an active layer situated between the first terminal and the second terminal, wherein the active layer includes a switching material, wherein the switching material is configured to be in a substantially conductive state in response to a voltage on the transmission line being in a range above a threshold voltage and in a substantially non-conductive state in response to the voltage on the transmission line being in a range below the threshold voltage.

In some aspects, the switching material includes a chalcogenide.

In some aspects, the threshold switching device includes an Ovonic threshold switching (OTS) switch.

In some aspects, the switching material includes a transition metal oxide, and the substantially conductive state is a metallic state, and the substantially non-conductive state is an insulating state. In some aspects, the transition metal oxide includes niobium dioxide (NbO₂) or chromium-doped vanadium sesquioxide (V₂O₃:Cr).

In some aspects, the threshold switching device is bipolar.

In some aspects, the transmission line termination circuit further includes a termination impedance, wherein the termination impedance includes a resistance. In some aspects, the resistance is inherent to the threshold switching device.

In some aspects, the transmission line termination circuit further includes a memory cell situated between and coupled to the second terminal of the threshold switching device and the second conductor of the transmission line, wherein the memory cell is characterized by an ON state in which the memory cell is configured to allow the threshold switching device to shunt current from the first conductor of the transmission line to the second conductor of the transmission line, and an OFF state in which the memory cell is configured to reduce a current shunted to the second conductor of the transmission line through the threshold switching device. In some aspects, the memory cell includes a phase change memory (PCM), a magnetoresistive random access memory (MRAM) cell, or a resistive random access memory (ReRAM) cell. In some aspects, the memory cell is non-volatile.

In some aspects, the transmission line termination circuit further includes circuitry coupled to the memory cell to allow a state of the memory cell to be set to the ON state or to the OFF state, and a controller coupled to the circuitry and configured to set the state of the memory cell using the circuitry. In some aspects, the circuitry includes at least one of a voltage source or a current source.

In some aspects, the transmission line termination circuit further includes a termination impedance, wherein the termination impedance includes a resistance. In some aspects, the resistance is inherent to the threshold switching device and/or the memory cell.

In some aspects, the transmission line termination circuit further includes a termination impedance, wherein the termination impedance includes a memory cell. In some aspects, a resistance of the memory cell is adjustable. In some aspects, the memory cell is non-volatile. In some aspects, the memory cell includes a phase change memory (PCM), a magnetoresistive random access memory (MRAM) cell, or a resistive random access memory (ReRAM) cell. In some aspects, the transmission line termination circuit further includes circuitry coupled to the memory cell to allow the resistance of the memory cell to be set, and a controller coupled to the circuitry and configured to set the resistance of the memory cell using the circuitry.

In some aspects, the transmission line termination circuit further includes a termination impedance, wherein the termination impedance includes a resistive network. In some aspects, the resistive network includes a plurality of memory cells in a parallel arrangement, and the transmission line termination circuit further includes circuitry coupled to each memory cell of the plurality of memory cells, and a controller coupled to the circuitry and configured to use the circuitry to configure the resistive network to provide a target resistance.

In some aspects, the plurality of memory cells includes a plurality of two-state memory cells, wherein at least one two-state memory cell of the plurality of two-state memory cells is configured to be in a first resistance state or a second resistance state depending on an applied voltage, and wherein the controller is configured to control whether the at least one of the plurality of two-state memory cells is in the first resistance state or the second resistance state. In some aspects, each memory cell of the plurality of memory cells is non-volatile. In some aspects, at least one memory cell of the plurality of memory cells includes a phase change memory (PCM), a magnetoresistive random access memory (MRAM) cell, or a resistive random access memory (ReRAM) cell.

In some aspects, the transmission line termination circuit further includes a first memory cell situated between and coupled to the second terminal of the threshold switching device and the second conductor of the transmission line, wherein the first memory cell is characterized by an ON state in which the first memory cell is configured to allow the threshold switching device to shunt current from the first conductor of the transmission line to the second conductor of the transmission line, and an OFF state in which the first memory cell is configured to reduce the current shunted to the second conductor of the transmission line from the first conductor of the transmission line through the threshold switching device; first circuitry coupled to the first memory cell to allow a state of the first memory cell to be set to the ON state or to the OFF state; and a first controller coupled to the first circuitry and configured to set the state of the first memory cell using the first circuitry.

In some aspects, the transmission line termination circuit further includes a termination impedance, wherein the termination impedance includes a second memory cell. In some aspects, a resistance of the second memory cell is adjustable. In some aspects, the transmission line termination circuit further includes second circuitry coupled to the second memory cell to allow the resistance of the second memory cell to be set, and a second controller coupled to the second circuitry and configured to set the resistance of the second memory cell using the second circuitry. In some aspects, the first controller and the second controller are a same controller. In some aspects, at least a portion of the first circuitry is shared by the second circuitry. In some aspects, at least one of the first memory cell or the second memory cell is non-volatile. In some aspects, at least one of the first memory cell or the second memory cell includes a phase change memory (PCM), a magnetoresistive random access memory (MRAM) cell, or a resistive random access memory (ReRAM) cell.

In some aspects, the transmission line termination circuit further includes a termination impedance, wherein the termination impedance includes a resistive network. In some aspects, the resistive network includes a plurality of additional memory cells in a parallel arrangement, and the transmission line termination circuit further includes second circuitry coupled to each memory cell of the plurality of additional memory cells, and a second controller coupled to the second circuitry and configured to use the second circuitry to configure the resistive network to provide a particular resistance. In some aspects, the plurality of additional memory cells includes a plurality of two-state memory cells, wherein at least one two-state memory cell of the plurality of two-state memory cells is configured to be in a first resistance state or a second resistance state depending on an applied voltage, and the second controller is configured to control whether the at least one of the plurality of two-state memory cells is in the first resistance state or the second resistance state. In some aspects, the first controller and the second controller are a same controller. In some aspects, at least a portion of the first circuitry is shared by the second circuitry.

In some aspects, at least one of the plurality of additional memory cells is non-volatile. In some aspects, the techniques described herein relate to a transmission line termination circuit, wherein the at least one of the plurality of additional memory cells includes a phase change memory (PCM), a magnetoresistive random access memory (MRAM) cell, or a resistive random access memory (ReRAM) cell.

In some aspects, the first memory cell is non-volatile. In some aspects, the first memory cell includes a phase change memory (PCM), a magnetoresistive random access memory (MRAM) cell, or a resistive random access memory (ReRAM) cell.

In some aspects, the techniques described herein relate to a transmission line termination circuit for terminating a transmission line, the transmission line termination circuit including: a first diode configured to be coupled to a first voltage source; a second diode configured to be coupled to a second voltage source, wherein an anode of the first diode is coupled to a cathode of the second diode; a tunable-resistance element coupled to the anode of the first diode and to the cathode of the second diode; circuitry coupled to the tunable-resistance element to allow a resistance of the tunable-resistance element to be set; and a controller coupled to the circuitry and configured to set the resistance of the tunable-resistance element using the circuitry.

In some aspects, the tunable-resistance element includes a memory cell. In some aspects, a resistance of the memory cell is programmable to at least three resistance values. In some aspects, the memory cell is non-volatile. In some aspects, the memory cell includes a phase change memory (PCM), a magnetoresistive random access memory (MRAM) cell, or a resistive random access memory (ReRAM) cell.

In some aspects, the tunable-resistance element includes a resistive network. In some aspects, the resistive network includes a plurality of memory cells in a parallel arrangement, and wherein the controller is configured to use the circuitry to configure the resistive network to provide a target resistance. In some aspects, the plurality of memory cells includes a plurality of two-state memory cells, wherein at least one two-state memory cell of the plurality of two-state memory cells is configured to be in a first resistance state or a second resistance state depending on an applied voltage, and the controller is configured to control whether the at least one two-state memory cell of the plurality of two-state memory cells is in the first resistance state or the second resistance state.

In some aspects, each of the plurality of memory cells is non-volatile. In some aspects, each of the plurality of memory cells includes a phase change memory (PCM), a magnetoresistive random access memory (MRAM) cell, or a resistive random access memory (ReRAM) cell.

In some aspects, the techniques described herein relate to a method of selectively terminating nodes of a transmission line, each of the nodes coupled to a respective termination circuit, each respective termination circuit including a respective threshold switching device coupled to a respective termination impedance and to a respective memory cell, each respective memory cell having an ON state and an OFF state, wherein, in the ON state, the respective memory cell allows the respective threshold switching device to route signals arriving at the respective node on a first conductor of the transmission line to a second conductor of the transmission line, and in the OFF state, the respective memory cell reduces current shunted from the first conductor of the transmission line to the second conductor of the transmission line through the respective threshold switching device, the method including: identifying which of the nodes should be terminated; and for each of the nodes that should be terminated, setting a state of the respective memory cell to the ON state to allow the respective threshold switching device at the respective node to route signals arriving at the respective node on the first conductor to the second conductor.

In some aspects, identifying which of the nodes should be terminated includes executing an optimization algorithm. In some aspects, the optimization algorithm includes a derivative-free optimization algorithm. In some aspects, the derivative-free optimization algorithm includes one or more of Nelder-Mead method, a Bayesian optimization, a direct search method, a Hooke-Jeeves algorithm, Powell's method, or simulated annealing.

In some aspects, identifying which of the nodes should be terminated includes: (a) setting a baseline configuration with all nodes unterminated; (b) determining a performance of the transmission line in the baseline configuration; (c) choosing a subset of one or more nodes; (d) creating a new configuration by, for each node of the subset of one or more nodes, setting the state of the respective memory cell to the ON state to couple the respective termination impedance to the respective node, thereby terminating each of the subset of one or more nodes; (e) determining a performance of the transmission line in the new configuration; and (f) determining whether the performance of the transmission line in the new configuration is preferred to the performance of the transmission line in the baseline configuration.

In some aspects, the performance of the transmission line in the baseline configuration is a first bit rate, and the performance of the transmission line in the new configuration is a second bit rate.

In some aspects, the method further includes: in response to determining that the performance of the transmission line in the new configuration is preferred to the performance of the transmission line in the baseline configuration, designating the new configuration as the baseline configuration; and repeating steps (c) through (f) for a new subset of one or more nodes, wherein the new subset of one or more nodes differs from the subset of one or more nodes.

In some aspects, the method further includes: before determining the performance of the transmission line in the new configuration, setting or adjusting the respective termination impedance of at least one node in the subset of one or more nodes. In some aspects, setting or adjusting the respective termination impedance of at least one node includes: executing an optimization algorithm to determine a value of the respective termination impedance for the at least one node. In some aspects, the optimization algorithm includes a derivative-free optimization algorithm. In some aspects, the derivative-free optimization algorithm includes one or more of Nelder-Mead method, a Bayesian optimization, a direct search method, a Hooke-Jeeves algorithm, Powell's method, or simulated annealing.

In some aspects, choosing the subset of one or more nodes of the transmission line includes: identifying a plurality of leaf nodes; and choosing, as the subset of one or more nodes, two nodes of the plurality of leaf nodes, the two nodes having a largest distance between them among the plurality of leaf nodes.

In some aspects, the method further includes: in response to determining that the performance of the transmission line in the new configuration is preferred to the performance of the transmission line in the baseline configuration, saving the new configuration as the baseline configuration; and repeating steps (c) through (f) for a new subset of one or more nodes, wherein the new subset of one or more nodes differs from the subset of one or more nodes, wherein choosing the new subset of one or more nodes of the transmission line includes choosing, as the new subset of one or more nodes, two or more nodes of the plurality of leaf nodes. In some aspects, the new subset of one or more nodes includes the two nodes having a largest distance between them among the plurality of leaf nodes.

In some aspects, each termination impedance is adjustable, and the method further includes: before determining the performance of the transmission line in the new configuration, setting a value of the respective termination impedance for at least one of the nodes in the subset of one or more nodes. In some aspects, setting the value of the respective termination impedance for at least one of the nodes in the subset of one or more nodes includes: executing an optimization algorithm to determine the value of the respective termination impedance for the at least one of the nodes in the subset of one or more nodes. In some aspects, the optimization algorithm includes a derivative-free optimization algorithm. In some aspects, the derivative-free optimization algorithm includes one or more of Nelder-Mead method, a Bayesian optimization, a direct search method, a Hooke-Jeeves algorithm, Powell's method, or simulated annealing.

### BRIEF DESCRIPTION OF THE DRAWINGS

Objects, features, and advantages of the disclosure will be readily apparent from the following description of certain embodiments taken in conjunction with the accompanying drawings in which:

FIG. 1A is a diagram illustrating an example of a network in which there are only two nodes.

FIG. 1B is a diagram illustrating an example of a network in which there are three nodes.

FIG. 1C is a diagram illustrating how the network should be modified to allow proper communication.

FIG. 1D is a diagram illustrating a more complicated network that includes five nodes.

FIG. 1E is a diagram representing a network in an example termination configuration.

FIG. 2 is an illustration of a conventional circuit for terminating a transmission line.

FIG. 3 is an illustration of an example of a new termination circuit in accordance with some embodiments.

FIG. 4A is a diagram of an example of a threshold switching device in accordance with some embodiments.

FIG. 4B is a plot illustrating behavior that can be expected of a threshold switching device in accordance with some embodiments.

FIG. 5 illustrates an example of a transmission line termination circuit that includes a memory cell situated between the threshold switching device and ground in accordance with some embodiments.

FIG. 6A illustrates an example of another transmission line termination circuit for terminating the transmission line in accordance with some embodiments.

FIG. 6B illustrates an example of another transmission line termination circuit for terminating the transmission line in accordance with some embodiments.

FIG. 6C illustrates an example of a resistive network in accordance with some embodiments.

FIG. 7 illustrates an example of another transmission line termination circuit in accordance with some embodiments.

FIG. 8 illustrates an example of another transmission line termination circuit in accordance with some embodiments.

FIG. 9A illustrates an example of a transmission line termination circuit that uses diodes and an adjustable/programmable termination impedance in accordance with some embodiments.

FIG. 9B illustrates an example of another transmission line termination circuit that uses diodes and an adjustable/programmable termination impedance in accordance with some embodiments.

FIG. 10 is a flow diagram illustrating a method of selectively terminating nodes of a transmission line using in accordance with some embodiments.

FIG. 11 is a flow diagram illustrating an example of a process of identifying which nodes should be terminated in accordance with some embodiments.

FIG. 12 is a flow diagram illustrating an example of a process of identifying a subset of nodes to be terminated in accordance with some embodiments.

To facilitate understanding, identical reference numerals have been used, where possible, to designate identical elements that are common to the figures. It is contemplated that elements disclosed in one embodiment may be beneficially utilized in other embodiments without specific recitation. Moreover, the description of an element in the context of one drawing is applicable to other drawings illustrating that element.

Some of the drawings herein illustrate multiple instances of a feature, with each feature designated by a common reference numeral followed by a different letter. For convenience, the detailed description sometimes refers to these features collectively using only the common reference numeral.

### DETAILED DESCRIPTION

As explained above, proper termination of transmission lines is important for a variety of reasons. Although the concept of line termination is simple, in practice, ensuring proper termination of transmission lines can be difficult. For example, in addition to the challenges described above, in some kinds of networks, such as buses that use daisy chains (multiple devices together in a linear sequence) or parallel connections, it may not be clear which node or nodes need to be terminated and which node or nodes simply need to pass signals. This problem is exacerbated if the topology of a network can change.

Furthermore, as hardware becomes more integrated, conventional termination approaches become less attractive and/or infeasible. There may be no space available for a termination circuit to be situated on a PCB. For example, some applications (e.g., DDR5) call for on-chip termination as opposed to circuit-level termination. In addition, it can be difficult and/or expensive to tightly control impedances on a PCB, and a specific power supply may be required to power the resistive termination.

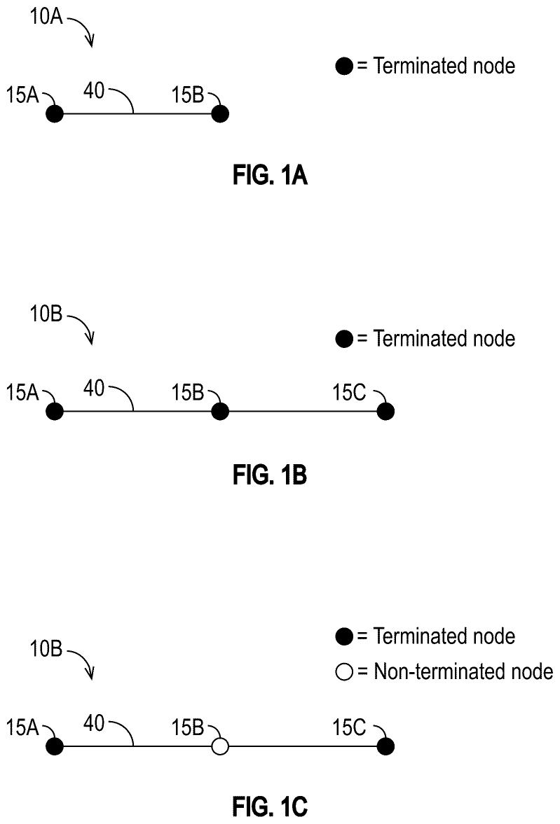

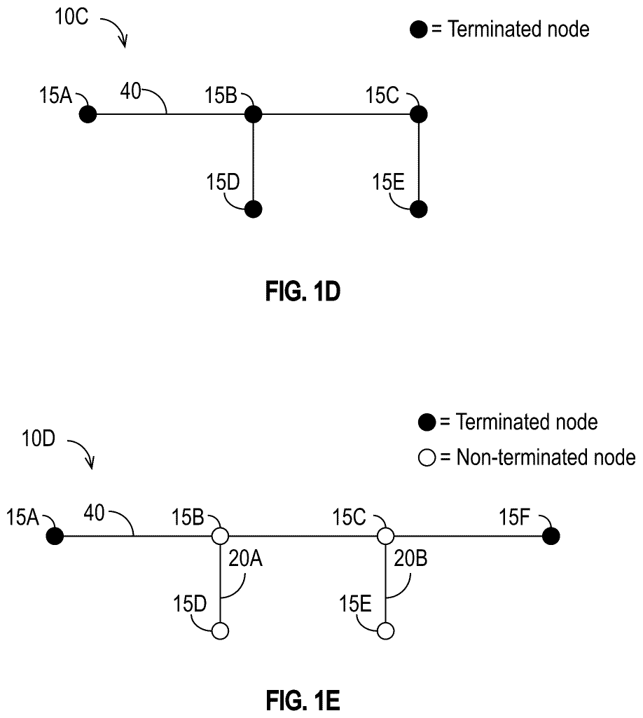

FIG. 1A is a diagram illustrating an example of a network 10A in which there are only two nodes. In this case, node 15A and node 15B are both terminated (ideally in the characteristic impedance of the line connecting them), and communication between the node 15A and the node 15B is possible without significant signal degradation.

FIG. 1B is a diagram illustrating another example of a network 10B in which there are three nodes. In the network 10B, a third node, the node 15C, has been added to the simple network 10A. The node 15C is connected to the node 15B. In this configuration, if all three nodes are terminated as illustrated, the network 10B might not work at all because the node 15B will absorb/block signals between the node 15A and the node 15C.

FIG. 1C is a diagram illustrating how the network 10B should be modified to allow proper communication between the node 15A and the node 15C. As shown, the node 15B should be non-terminated (also referred to herein as unterminated or not terminated) so that signals can pass through the node 15B.

Although the concept of line termination is simple, and it is relatively easy to determine which nodes in simple networks (e.g., the network 10A of FIG. 1A) and the network 10B of FIGS. 1B and 1C) should be terminated and which should not be terminated, it can be challenging to make this determination in more complicated networks or in networks in other configurations (e.g., networks in more of a star topology). As an example, FIG. 1D is a diagram illustrating a more complicated network that includes five nodes. The network 10C shown in FIG. 1D includes a node 15A connected in series to a node 15B, which is connected in series to a node 15C. In addition, the node 15B is connected to a node 15D, and the node 15C is connected to a node 15E. The best termination strategy for the network 10C is not immediately apparent.

FIG. 1E is a diagram representing a network 10D in an example termination configuration. The network 10D could be, for example, a CAN bus network. The node 15A and the node 15F are terminated in the characteristic impedance of the transmission line (e.g., 120 Ohms for a CAN bus network). To limit signal reflections to tolerable levels, the lengths of the line 20A and the line 20B can be limited (e.g., to 0.3 m) so that when one or both of the node 15D and/or node 15E is left unterminated as shown in FIG. 1E (in which case they may be referred to as “stubs”), signal reflections do not cause catastrophic signal reflections.

Although limiting the maximum lengths of unterminated stubs of transmission line as described in the discussion of FIG. 1E is one way to mitigate the effects of signal reflections due to unterminated nodes, it is suboptimal because it limits flexibility of the network. There may be situations in which a topology such as shown in FIG. 1E is needed, and it is not possible to limit the length of the line 20A and/or the line 20B to lengths at which reflections are tolerable.

What is needed is a more flexible solution to termination of transmission lines, and preferably a solution that does not restrict the lengths of stubs, but rather allows them to be terminated more easily than prior art solutions. There is also a need generally for line termination approaches that are cost-effective and do not suffer from all of the drawbacks of known active and passive approaches. Also needed is a way to determine workable termination impedance settings for a network or bus (e.g., to determine which node(s) should be terminated and then terminate those nodes, and/or to determine what termination impedances should be used and then provide those termination impedances, etc.).

Disclosed herein are new apparatuses and methods for improving line termination. In some embodiments, at least one threshold switching device is included in a termination circuit to provide a compact node termination circuit. In some embodiments, the termination circuit for each node includes at least one threshold switching device, which can comprise, for example, an Ovonic threshold switching (OTS) switch, a niobium dioxide (NbO₂) switch, and/or a V₂O₃:Cr switch. The described threshold switching devices are fast and physically small, making them advantageous relative to conventional switches. Moreover, the disclosed threshold switching devices can be integrated in the metallization layer of a chip, using existing fabrication processes. For example, the disclosed line termination circuits can be easily integrated, at low cost, into a memory chip that already includes memory cells that use threshold switching (e.g., MRAM, ReRAM, PCM, etc.).

In some embodiments, a programmable termination resistance is provided to allow the termination impedance of the node termination circuit to be adjusted. The programmable termination resistance may be provided using one or more memory cells. Programmable termination resistance can be used with or without a threshold switching device.

Also disclosed herein are techniques for determining which terminations of a network to enable (e.g., which nodes to terminate and which to leave unterminated).

Also disclosed are optimization techniques that can be used to improve network performance and compensate for electrical imperfections.

A technique that can be used to dynamically adjust the termination impedance to match the characteristic impedance of a transmission line is called forced perfect termination (FPT). An FPT solution can adapt to changes in signal characteristics or environmental conditions in real-time, thereby improving impedance matching. The objective is to ensure that, on average, over time, the termination impedance is neither too high nor too low. In an implementation, a termination circuit is provided that can switch between a state in which the impedance is too high and a state in which the impedance is too low fast enough that, on average, the termination impedance is the correct value.

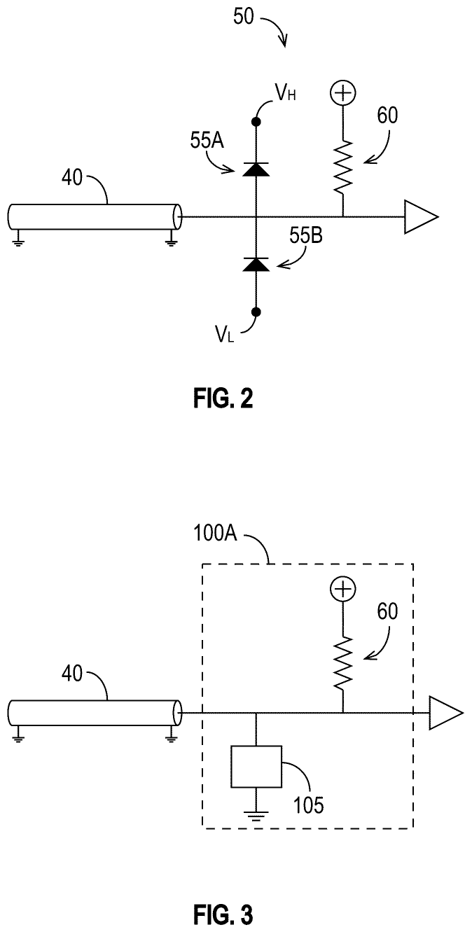

There are a number of conventional circuits that can implement FPT. FIG. 2 is an illustration of one such conventional circuit for terminating a transmission line 40. The circuit 50 shown in FIG. 2 includes a first diode 55A, a second diode 55B, and a termination resistance, illustrated as a resistor 60. (It is to be appreciated that the resistor 60 could be a network of resistors, an RLC circuit, or other hardware. Similarly, the first diode 55A and/or second diode 55B could be other devices configured to operate as diodes (e.g., transistors).) As shown in FIG. 2, the cathode of the first diode 55A is connected to a voltage V_{H}, and the anode is connected to the cathode of the second diode 55B. The anode of the second diode 55B is connected to a voltage V_{L}. The resistor 60 is connected to a supply voltage to reduce current when the transmitter is idle. The supply voltage could be, for example, half of the maximum voltage of the signal on the transmission line 40. FIG. 2 also shows an amplifier, which is not part of the circuit 50. The amplifier is shown to symbolize a circuit that may be present in an implementation to convert the received signals to whatever level is needed in the receiver.

The circuit 50 shown in FIG. 2 removes undervoltage and overvoltage conditions. The voltage V_{H} is the maximum positive amplitude of the signal on the transmission line 40 plus the voltage drop across the first diode 55A. If the pulse level at the end of the transmission line 40 (the end with the circuit 50) exceeds V_{H}, the first diode 55A turns on, the termination impedance goes to zero, and the signal is grounded. The first diode 55A then turns off almost immediately, which causes the termination impedance to be too high again. The first diode 55A will then turn on again, causing the termination impedance to go to zero and the signal to go to ground.

Similarly, the voltage V_{L} is the maximum negative amplitude of the signal on the transmission line 40 minus the voltage drop across the second diode 55B. If the pulse level at the end of the transmission line 40 drops below V_{L}, the second diode 55B turns on, the termination impedance goes to zero, and the signal is grounded. The second diode 55B then turns off almost immediately, which causes the termination impedance to be too high again. The second diode 55B will then turn on again, causing the termination impedance to go to zero and the signal to go to ground.

As a result of the configuration of the first diode 55A and the second diode 55B, the signal is kept at a voltage between V_{H} and V_{L}. Thus, the first diode 55A and second diode 55B remove over-shoot and under-shoot by locking the signal between V_{H} and V_{L}.

The conventional approach shown in FIG. 2 and discussed above suffers from several drawbacks, especially as hardware solutions become smaller and more integrated. For example, the first diode 55A and second diode 55B can be physically-large components as compared to other hardware, and there may be insufficient area on a PCB to include them, or there may be no PCB at all. Other problems are power consumption of, and heat dissipation for, the first diode 55A, the second diode 55B, and the resistor 60. It would be desirable to find a more power-efficient, smaller solution.

### Forced Perfect Termination (FPT) Using a Threshold Switching Device

FIG. 3 is an illustration of an example of a new termination circuit in accordance with some embodiments. The transmission line termination circuit 100A includes a resistor 60 as the termination impedance, and a threshold switching device 105 instead of the first diode 55A and the second diode 55B. As shown in FIG. 3, one terminal of the threshold switching device 105 is coupled to the transmission line 40, and the other terminal is coupled to ground. It will be appreciated by those having ordinary skill in the art that the terminal of the threshold switching device 105 is coupled to one of the conductors of the transmission line 40, and the ground symbols used herein symbolize a second conductor of the transmission line 40. As will be understood, most transmission lines 40 function by using two conductors that carry electrical signals from one point to another. In some types of transmission lines 40, one conductor (e.g., a first conductor coupled to the threshold switching device 105) provides a forward path and the other conductor (e.g., a second conductor of the transmission line 40) provides a return path. For example, a coaxial cable has an inner conductor that carries the signal and an outer conductor (shield) that serves as a return path, with the inner and outer conductors being separated by an insulating layer. Other types of transmission line 40 use two conductors to carry two complementary signals (positive and negative), thereby providing differential signaling. Each conductor carries a signal that is the inverse of the other, and the difference between these signals represents the transmitted data. For example, a twisted-pair line uses two insulated conductors twisted together to reduce electromagnetic interference (EMI). A parallel wire line (sometimes called a twin-lead) has two parallel conductors separated by an insulating material. It is also possible for transmission to be successful using a single, high-voltage conductor with the Earth as the return path. For simplicity, the drawings herein show, and the description sometimes refers to, one of the conductors used in the transmission line 40 as “ground.” It is to be appreciated that, in general, the conductor referred to as “ground” is not necessarily grounded. As will be appreciated, the various transmission line termination circuits described herein can be coupled to the two conductors used by the transmission line 40 to transmit signals in any suitable manner (e.g., using single-ended signaling, differential signaling, etc.). These two conductors are referred to as the first conductor and the second conductor, with the second conductor being represented by the ground symbol and sometimes referred to as ground.

As explained further herein, a threshold switching device 105 is a type of electronic component that exhibits a sudden change in resistance when the applied voltage or current reaches a specific threshold value. The threshold switching device 105 includes an active layer comprising a switching material that undergoes a structural change (e.g., formation of a conductive filament, a change in the local structure of the material, etc.) in response to an applied voltage. The material acts like an insulator (high-resistance state) in response to an applied voltage being in a range below a threshold voltage (or threshold current) and like a conductor (low-resistance state) in response to the applied voltage (or current) exceeding the threshold. As described further below, the threshold switching device 105 can be, for example, an Ovonic threshold switching (OTS) switch, an NbO₂ switch, or a V₂O₃:Cr switch.

The threshold switching device 105 shown in FIG. 3 is bipolar (sometimes referred to as non-polarized) meaning that it operates equally well regardless of the polarity of the voltage applied to it. Accordingly, the threshold switching device 105 shown in FIG. 3 can switch states in response to voltages of either polarity and can replace both the first diode 55A and the second diode 55B of FIG. 2. Although FIG. 3 shows a single, bipolar threshold switching device 105, it is to be appreciated that a pair of unipolar threshold switching devices connected in parallel could be used instead of the illustrated bipolar threshold switching device 105. Such a configuration could be useful if, for example, different switching behavior or properties are desirable for positive and negative voltages. The discussion below refers only to positive voltages for simplicity.

It is to be appreciated that although the discussion herein generally refers to the threshold switching device 105 responding to an applied voltage, the device could be described instead as responding to an applied current. In this case, the threshold switching device 105 will change from its high-resistance state to its low-resistance state when the current strays above a threshold current (and, in the other direction, from its low-resistance to its high-resistance state when the current falls below a threshold, which might not be the same threshold).

It is also to be appreciated that although FIG. 3 illustrates the transmission line termination circuit 100A with a resistor 60 as the termination impedance, the resistor 60 may be omitted, in which case the inherent resistance of the threshold switching device 105 itself provides the termination impedance for the transmission line termination circuit 100A.

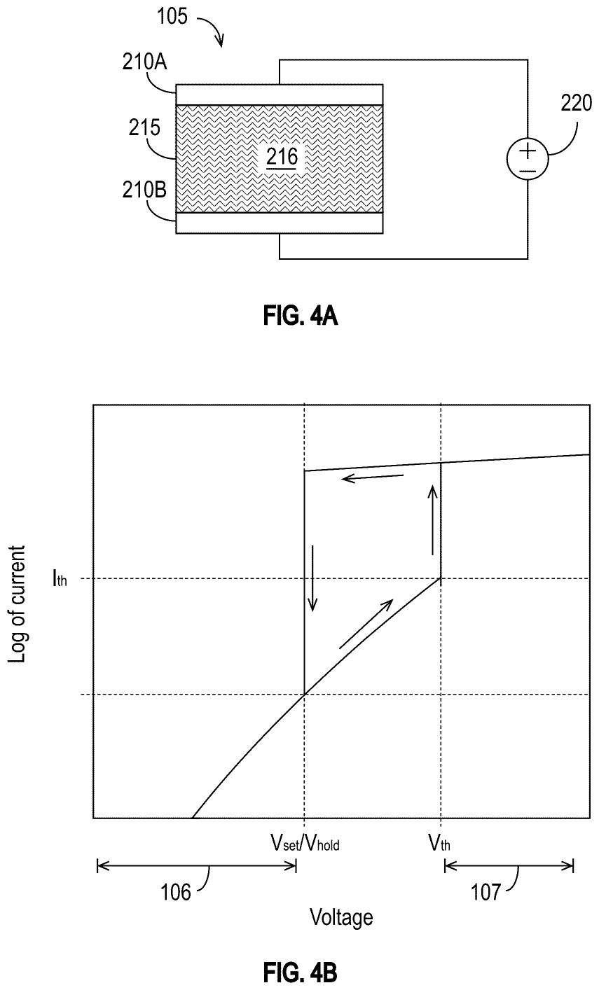

FIG. 4A is a diagram of an example of a threshold switching device 105 in accordance with some embodiments. The threshold switching device 105 example shown in FIG. 4A includes a first electrode 210A, a second electrode 210B, and an active layer 215 between the first electrode 210A and the second electrode 210B. The threshold switching device 105 has no orientation (it is non-directional), and there is no difference between the first electrode 210A and the second electrode 210B. In other words, the threshold switching device 105 is non-directional in addition to being bipolar.

The active layer 215 includes (or is made of) a switching material 216. A defining characteristic of the switching material 216 is that it undergoes a rapid state change in response to an applied voltage (or current) exceeding, or falling below, a threshold. In a range below the threshold voltage (or current), the switching material 216 acts like an insulator (high-resistance, off) and allows little current to flow through the switching material 216. In a range above the threshold voltage (or current), the switching material 216 acts like a conductor (low-resistance, on) and allows significant current to flow through the switching material 216. The switch from the high-resistance state to the low-resistance state is rapid, typically occurring in nanoseconds. Thus, the switching material 216 allows the threshold switching device 105 to switch more quickly than the first diode 55A and second diode 55B shown in FIG. 2.

As will be explained further in the discussion of FIG. 4B, the voltage threshold at which the switching material 216 changes its state (from low-resistance to high-resistance, or vice versa) may be different depending on whether the applied voltage is increasing or decreasing (i.e., whether the threshold switching device 105 is transitioning from the high-resistance state to the low-resistance state, or vice versa).

The switching material 216 can be (or comprise) any material that exhibits a state change like those described herein. It is to be appreciated that specific examples are described, but the disclosures are not limited to those examples.

In some embodiments, the switching material 216 is (or comprises) a chalcogenide. Chalcogenides are compounds that include at least one chalcogen element and one or more electropositive elements (e.g., metals (e.g., Ge, Sb) or semimetals). The chalcogen elements are in Group 16 of the periodic table, and they include oxygen (O), sulfur (S), selenium (Se), tellurium (Te), and polonium (Po). Chalcogenides include, for example, GeTe (germanium telluride), As—Si—Te (arsenic-silicon-tellurium), and Ge—S—Te (germanium-silicon-tellurium). Chalcogenide materials undergo a rapid, reversible transition between an amorphous, high-resistance (off) state in which the material acts like an insulator, and current flow is minimal, and a crystalline, low-resistance (on) state in which the material acts like a conductor, and there is a substantial increase in current.

When the active layer 215 of the threshold switching device 105 includes a chalcogenide as the switching material 216, in the amorphous, high-resistance (off) state, the electronic structure of the material is such that charge carriers are not freely mobile. In this state, the switching material 216 is said to be substantially non-conductive. The switching material 216 stays in the amorphous state until the applied voltage exceeds specific threshold voltage (Vₜₕ), at which point the material rapidly (typically in nanoseconds) switches to the crystalline state. In the crystalline, low-resistance (on) state, the electronic structure of the switching material 216 allows for the rapid movement of charge carriers. In this state, the switching material 216 is substantially conductive. When the applied voltage drops below a certain holding voltage (V_{hold}), the switching material 216 rapidly (again, typically in nanoseconds) reverts back to the high-resistance state.

The properties of a chalcogenide can be tuned by varying its composition and stoichiometry. Thus, the threshold voltage Vₜₕ and the holding voltage V_{hold} can be controlled and designed based on the material composition and structure. For example, for the transmission line termination circuit 100A shown in FIG. 3, the material composition and structure of the chalcogenide can be selected based on the maximum expected voltage (positive and/or negative) on the transmission line 40.

When the switching material 216 comprises (or is) a chalcogenide, the threshold switching device 105 can be referred to as an Ovonic threshold switching (OTS) device, an OTS switch, or simply an OTS. OTS switches can be bipolar, like the threshold switching device 105 shown in FIG. 3, so that they can operate with both positive and negative voltage pulses. Accordingly, they can switch states in response to voltages of either polarity.

As an alternative to chalcogenides, the switching material 216 can be (or comprise), for example, a transition metal oxide (TMO). Transition metal oxides are compounds that have oxygen atoms bonded to transition metals. Transition metals are elements found in the d-block of the periodic table (e.g., titanium, vanadium, chromium, manganese, iron, cobalt, nickel, copper, zinc). When the switching material 216 comprises a TMO, the threshold switching device 105 can be referred to as a TMO switch (or a TMO device).

The conductivity of TMOs can range from insulating to conducting. TMOs include NbO₂ (niobium dioxide) and V₂O₃:Cr (chromium-doped vanadium sesquioxide), both of which are examples of compounds that can be used as the switching material 216. As noted above, however, the disclosures herein are not limited to these particular examples. Any suitable TMO could be used.

In some embodiments, the 216 is (or comprises) NbO₂, and the threshold switching device 105 can be referred to as an NbO₂ switch. NbO₂ switches leverage the ability of NbO₂ to undergo rapid (on the other of nanoseconds) metal-to-insulator transitions (MIT) and its threshold switching characteristics. Like a chalcogenide, NbO₂ is characterized by a characteristic threshold voltage (Vₜₕ) at which it switches from a high-resistance state (insulating, at voltages below Vₜₕ) to a low-resistance state (metallic, at voltages above Vₜₕ). The switching is reversible, allowing the device to return to its high-resistance state when the voltage falls below a holding voltage (V_{hold}). Like OTS switches, NbO₂ switches can be bipolar so that they can operate with both positive and negative voltage pulses. Accordingly, they can switch states in response to voltages of either polarity.

In some embodiments, the switching material 216 comprises (or is) V₂O₃:Cr, and the threshold switching device 105 can be referred to as a V₂O₃:Cr switch. V₂O₃:Cr switches use vanadium sesquioxide (V₂O₃) doped with chromium (Cr). Such switches exploit the MIT characteristics of V₂O₃ enhanced by chromium doping. The MIT in V₂O₃:Cr can be sensitive to temperature, and the exact transition temperature can be controlled by the amount of Cr doping. The threshold voltage for switching can also be tuned based on the doping level of chromium and the properties of the V₂O₃ material. At or near the transition temperature, V₂O₃:Cr is in a high-resistance (insulating) state, and minimal current flows. When a voltage is applied across the V₂O₃:Cr switch and exceeds a threshold (Vₜₕ), the material undergoes a rapid transition from the insulating state to a metallic state, similarly to NbO₂. In this low-resistance state, V₂O₃:Cr behaves like a metal, with much lower resistance, allowing a large current to flow through. The V₂O₃:Cr switch remains in the low-resistance state as long as the applied voltage or current is maintained above the threshold. When the applied voltage is removed or drops below the holding voltage (V_{hold}), V₂O₃:Cr reverts to its high-resistance (insulating) state, resetting the switch. V₂O₃:Cr switches can be bipolar so that they can operate with both positive and negative voltage pulses. Accordingly, they can switch states in response to voltages of either polarity.

In the example shown in FIG. 4A, the active layer 215 is illustrated as being in contact with the first electrode 210A and the second electrode 210B, each of which may be made of one or more metals (e.g., titanium, tungsten, platinum, etc.). The material(s) of the first electrode 210A and the second electrode 210B may be chosen for their electrical conductivity and compatibility with the switching material 216. Optionally, additional buffer layers can be included between the first electrode 210A and the switching material 216 (and between the second electrode 210B and the switching material 216) to enhance performance and stability (e.g., to control the interface properties and reduce the diffusion of electrode materials into the active layer 215).

In FIG. 4A, the first electrode 210A and second electrode 210B are shown coupled to a voltage source 220, which can be used to control the state of the threshold switching device 105 by applying a voltage across the threshold switching device 105. FIG. 4B is a plot illustrating the behavior that can be expected of a threshold switching device 105 (e.g., an OTS switch, an NbO₂ switch, a V₂O₃:Cr switch). The x-axis is the applied voltage (e.g., the voltage applied by the voltage source 220 of FIG. 4A, or the voltage on the transmission line 40 when the threshold switching device 105 is in the transmission line termination circuit 100A of FIG. 3, where “voltage on the transmission line 40” refers to the electric potential difference between the conductors within the transmission line 40 used to convey the signal, or between a conductor and ground, at the transmission line termination circuit 100A.). The y-axis, which is a logarithmic scale, is the current flowing through the threshold switching device 105. As shown in FIG. 4B, the IV characteristics of the threshold switching device 105 include a hysteresis loop. FIG. 4B includes arrows to indicate the direction of the loop.

As shown in FIG. 4B, at voltages in a range 106 that is below Vₜₕ, the switching material 216 is in a high-resistance state, which allows minimal current to flow between the first electrode 210A and the second electrode 210B. In this state, the threshold switching device 105 acts as an insulator. In other words, at low voltages, the current is minimal, and the threshold switching device 105 is substantially non-conductive, open, or off.

When the voltage applied across the threshold switching device 105 exceeds the threshold voltage Vₜₕ, the switching material 216 undergoes a rapid change in its conductive properties, transitioning rapidly (e.g., in nanoseconds) from the high-resistance state to the low-resistance state. The current increases drastically due to the phase change (e.g., for an OTS switch) or MIT (e.g., for a TMO switch) of the switching material 216 (e.g., for an OTS switch, the transition from the amorphous state to the crystalline state; for a TMO switch, the transition from the insulating state to the metallic state). In this state, significant current can flow between the first electrode 210A and the second electrode 210B, and the threshold switching device 105 acts as a conductor. In other words, it is substantially conductive or on. Stated another way, the threshold switching device 105 acts as a closed switch in the substantially conductive state. As noted above, the threshold voltage can be engineered via selection of the material composition and structure of the switching material 216 used in the threshold switching device 105.

At applied voltages in a range 107 above Vₜₕ, the threshold switching device 105 remains in the substantially-conductive state, and, ideally, the current continues to increase, but less rapidly. In practice, if the current increases substantially above Vₜₕ, the voltage can suddenly drop while the current remains high. This phenomenon creates a characteristic “snapback” in the I-V curve (not shown in FIG. 4B), where the threshold switching device 105 momentarily exhibits negative differential resistance. Repeated snapback events can lead to degradation of the device over time. It is desirable for the threshold switching device 105 to have limited snapback for transmission line termination so that the threshold switching device 105 behaves similarly to a steep diode.

When the threshold switching device 105 has been in the substantially conductive state, as the applied voltage is decreased (e.g., the voltage applied by the voltage source 220 in FIG. 4A decreases, or the voltage on the transmission line 40 of FIG. 3 decreases), the threshold switching device 105 initially remains in the low-resistance (substantially conductive, closed, on) state, even at voltages somewhat lower than Vₜₕ. Thus, the threshold switching device 105 can be said to have memory.

When the applied voltage drops below a hold voltage (shown as Vₛₑₜ/V_{hold} in FIG. 4B), the threshold switching device 105 switches (reverts) to the high-resistance (substantially non-conductive, open, off) state, and the current decreases drastically due to the phase change (e.g., of an OTS switch) or MIT (e.g., for a TMO switch) of the switching material 216 (e.g., for an OTS switch, the transition from the crystalline state to the amorphous state; for a transition metal oxide switch, the transition from the metallic state to the insulating state). In this state, the threshold switching device 105 is substantially non-conductive or off. Stated another way, the threshold switching device 105 acts as an open switch.

Thus, the threshold switching device 105 is substantially non-conductive (off, open, high-resistance) in a range 106 that is below both Vₜₕ and V_{hold}, and it is substantially conductive (on, closed, low-resistance) in a range 107 that is above both Vₜₕ and V_{hold}. Between V_{hold} and Vₜₕ, the threshold switching device 105 is substantially conductive or substantially non-conductive depending on whether the voltage is increasing or decreasing.

Referring back to FIG. 3, the threshold voltage of the threshold switching device 105, Vₜₕ, is the maximum amplitude of the signal (the maximum electrical potential difference between conductors used for signaling) on the transmission line 40. When the transmission line termination circuit 100A is in operation, if the signal level (the electrical potential difference between the two conductors (a first conductor and a second conductor) used to carry signals on the transmission line 40) that reaches the circuit 100A exceeds Vₜₕ, the threshold switching device 105 turns on, the termination impedance goes to zero, and the signal is grounded (shunted to the second conductor of the transmission line 40, which provides the return path). The threshold switching device 105 then turns off as soon as the voltage on the transmission line 40 (the electric potential difference between first and second conductors of the transmission line 40 at the transmission line termination circuit 100A) drops below the holding voltage (V_{hold}), which, as explained in the context of FIG. 4B, is typically slightly lower than Vₜₕ, which causes the termination impedance to be too high again. The threshold switching device 105 will then turn on again, causing the termination impedance to go to zero and the signal to go to ground (the second conductor of the transmission line 40). The cycle repeats whenever the signal strays above Vₜₕ.

Thus, including the threshold switching device 105 shown and described in the context of FIGS. 4A and 4B allows the transmission line termination circuit 100A shown in FIG. 3 to provide substantially the same functionality as the circuit 50 shown in FIG. 2. But the threshold switching device 105 provides that functionality in a different way than a diode.

For example, a key difference between the first diode 55A and the second diode 55B of FIG. 2 and the threshold switching device 105 of FIG. 3 is that the threshold switching device 105 is biased only by the voltage or current is on the transmission line 40. In other words, the threshold switching device 105 does not require, and is not subjected to, any external bias voltage or bias current. Instead, the threshold switching device 105 is connected to the two conductors of the transmission line 40 that are used to carry signals (or, in the case that the transmission line 40 includes only one conductor, between the transmission line 40 and ground).

Therefore, the threshold switching device 105 requires no power source but still provides switching functionality to implement FPT. In contrast, the first diode 55A and second diode 55B require a bias voltage or bias current, provided by V_{H} and V_{L} in FIG. 2, to operate. Thus, the transmission line termination circuit 100A of FIG. 3 consumes less power than the circuit 50 of FIG. 2.

Another key difference is that the first diode 55A and second diode 55B in the circuit 50 are directional (sometimes referred to as polarized) and must be situated in the circuit 50 with particular orientations to provide the desired functionality. For example, the first diode 55A and second diode 55B must be installed with the correct polarity to allow current to flow in the intended direction because diodes include semiconductor materials in a PN junction that behaves differently under forward-and reverse-bias conditions. Therefore, it is important to distinguish between the anode and the cathode and to ensure that the first diode 55A and second diode 55B have the proper orientation. In contrast, as explained above, the threshold switching device 105 is non-directional (also referred to as non-polarized), meaning that it functions the same way regardless of its orientation in the circuit.

In addition, as explained above, the threshold switching device 105 is bipolar and can operate equally well regardless of the polarity of the voltage applied to it. Thus, a single threshold switching device 105 can replace both the first diode 55A and the second diode 55B.

The threshold switching device 105 can also be fabricated at small scales, thereby allowing the transmission line termination circuit 100A of FIG. 3 to be more compact than the circuit 50 of FIG. 2. The first diode 55A and second diode 55B can be replaced by a single bipolar threshold switching device 105, which can be integrated into the metallization of a chip, and the voltage sources needed for the first diode 55A and second diode 55B, and the wiring for them, are eliminated. Thus, the transmission line termination circuit 100A can be included in designs in which it might be infeasible or too costly to include the circuit 50.

Thus, the benefits of using a threshold switching device 105 in a transmission line termination circuit can include, for example, any or all of the following: low power consumption, fast switching speed, controllable threshold voltage (or current), reliable operation over a wide temperature range, ability to withstand many switching cycles without significant degradation, stability, and small size.

### Selectively Terminating Transmission Line Nodes

As explained above and illustrated in FIGS. 3, 4A, and 4B, the transmission line termination circuit 100A shown in FIG. 3 can be used to implement FPT for a node of a transmission line 40. As previously explained, it can be desirable to be able to control whether a node is terminated or non-terminated. In other words, it can be desirable to have a way selectively terminate nodes.

Some conventional networks use dual in-line package (DIP) switches to set node terminations. For each node that might need to be terminated (or left unterminated), a termination resistor (or more complicated circuit) that is selected to match the impedance of the transmission line (or bus) is placed in series with a DIP switch. The DIP switch is then set so that it either connects the termination resistor to the line or disconnects the termination resistor from the line. When the DIP switch is in the “ON” position, it completes the circuit, connecting the termination resistor across (and thereby terminating) the transmission line. When the DIP switch is in the “OFF” position, the circuit is open, and the termination resistor is disconnected from the transmission line, which is then unterminated.

Although DIP switches are a relatively simple, flexible, and cost effective approach to line termination, there are a number of drawbacks to using DIP switches for termination. A significant disadvantage is the potential for human error. Incorrectly setting DIP switches can lead to improper termination, causing signal reflections and degraded signal integrity. In more extreme cases, the network might not start up at all, and/or communication between some or all of the nodes might not be possible. Furthermore, DIP switches are static, and, once set, they provide static termination settings. Dynamic adjustment based on system conditions or diagnostics is not possible without manual intervention. To allow manual intervention, DIP switches need to be physically accessible to be switched from “ON” to “OFF” (or vice versa). In densely packed or enclosed systems, accessing and configuring the switches can be difficult, leading to potential inconvenience and/or the need to disassemble parts of the system.

Durability of DIP switches can also be an issue. Repeated switching can lead to wear and tear on the mechanical parts of the DIP switch, potentially leading to failures over time, which can compromise the reliability of the termination settings. DIP switches can also suffer from poor contact reliability over time, especially in environments with vibration, dust, or humidity, which can lead to intermittent connections and unreliable termination. Even though DIP switches are compact, they still require space on a PCB. In some applications, allocating space for DIP switches can be challenging.

Accordingly, in some embodiments, techniques are provided to allow a node to be selectively terminated or non-terminated. In some embodiments, the threshold switching device 105 is coupled to a memory cell that enables or disables termination of a node of the transmission line 40. In other words, the memory cell can be used to selectively terminate a node. This capability can be useful, for example, to address situations such as shown in FIGS. 1C, 1D, and 1E, where it is not known in advance which nodes should be terminated and which should not.

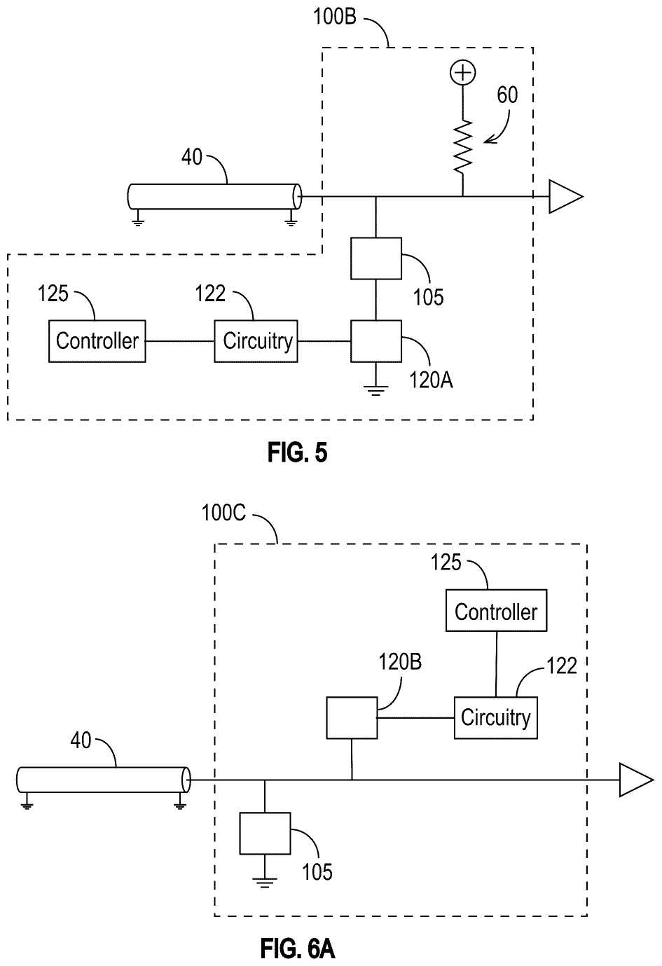

FIG. 5 is an illustration of an example of a transmission line termination circuit 100B in accordance with some embodiments. The transmission line termination circuit 100B of FIG. 5 is similar to the transmission line termination circuit 100A of FIG. 3, except that the transmission line termination circuit 100B includes a memory cell 120A situated between the threshold switching device 105 and ground (which may be the second conductor of the transmission line 40). The memory cell 120A is coupled to one of the terminals of the threshold switching device 105 (either first electrode 210A or second electrode 210B).

In some embodiments, the memory cell 120A is non-volatile and has two states, namely, a high-resistance state and a low-resistance state. When the memory cell 120A is in the high-resistance state, it prevents the threshold switching device 105 from shunting the current from the transmission line 40 to ground (the second conductor of the transmission line 40), thereby disabling the operation of the threshold switching device 105 and causing the transmission line termination circuit 100B to present high impedance to signals from the transmission line 40. Thus, when the memory cell 120A is in the high-resistance state, the node appears to be an open circuit and, therefore, unterminated. In contrast, when the memory cell 120A is in the low-resistance state, it allows the threshold switching device 105 to shunt the current to ground (the second conductor of the transmission line 40) as described above for the transmission line termination circuit 100A. Thus, the transmission line termination circuit 100B implements node termination by the threshold switching device 105 switching on and shunting the signal from a first conductor of the transmission line 40 to a second conductor of the transmission line 40 whenever the voltage on the transmission line 40 exceeds Vₜₕ, and otherwise presenting the resistance of the resistor 60 to the transmission line 40. Thus, the memory cell 120A allows the termination mechanism to be enabled or disabled so that the node is either terminated or effectively not terminated.

The memory cell 120A can be any suitable device that is operable to present a high resistance or a low resistance, depending on its programming. For example, the memory cell 120A can be a resistive random access memory (ReRAM), a phase-change memory (PCM), a magnetoresistive random access memory (MRAM), or any other suitable memory cell. The memory cell 120A can include the same kinds of materials as described above for the switching material 216 of the threshold switching device 105. The memory cell 120A has an ON (low-resistance, closed) state in which it allows the threshold switching device 105 to shunt signals to ground (the second conductor of the transmission line 40), and an OFF (high-resistance, open) state in which the memory cell 120A reduces the current shunted by the threshold switching device 105 to ground (the second conductor of the transmission line 40), thereby effectively removing the threshold switching device 105 from the transmission line termination circuit 100B and presenting high impedance to the transmission line 40 (effectively causing the node to be unterminated).

As shown in the example of FIG. 5, the memory cell 120A can be coupled to circuitry 122, which can be coupled to a controller 125. The circuitry 122 may comprise, for example, one or more of wiring, a voltage source, a current source, and/or any other component that allows the state of the memory cell 120A to be set or changed. The controller 125 is configured use the circuitry 122 to set the state of the memory cell 120A (e.g., to the ON (low-resistance) state or to the OFF (high-resistance) state).

To prevent ordinary signals sent over the transmission line 40 from changing the state of the memory cell 120A, the memory cell 120A may be selected so that changing its state (writing to the memory cell 120A) requires a write current that is higher than the current expected for typical signals on the transmission line 40.

It is to be appreciated that although FIG. 5 illustrates the transmission line termination circuit 100B with a resistor 60, the resistor 60 may be omitted, in which case the resistance due to the threshold switching device 105 in series with the memory cell 120A is the termination impedance provided by the transmission line termination circuit 100A.

### Tunable Termination Resistance

FIGS. 3 and 5 illustrate the transmission line termination circuit 100A and transmission line termination circuit 100B with a purely resistive termination, namely the resistor 60. As an alternative to a purely resistive termination, the resistor 60 can be replaced by a tunable-resistance memory cell 120B.

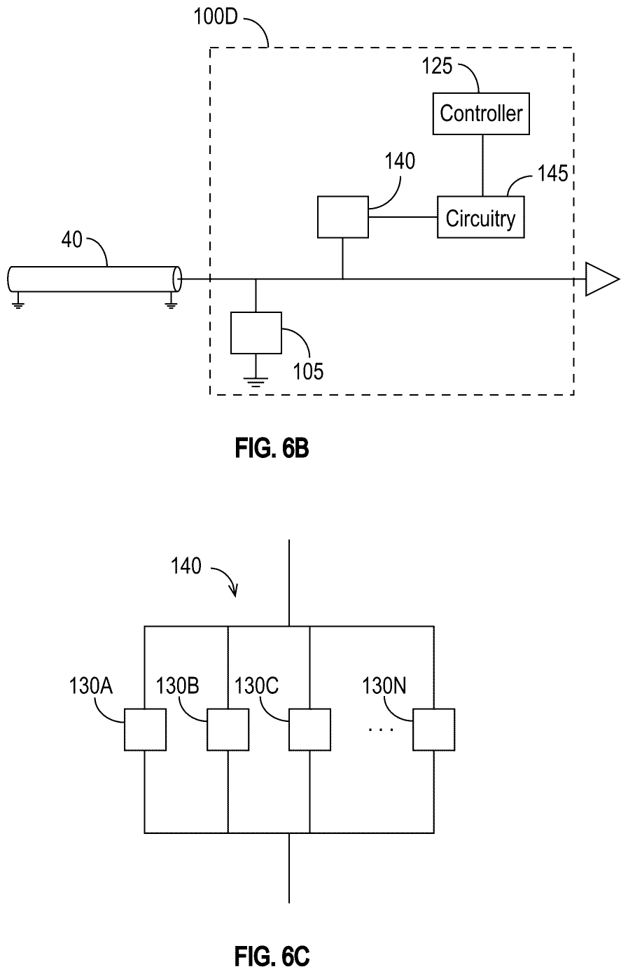

FIG. 6A is an example of a transmission line termination circuit 100C for terminating a transmission line 40 in accordance with some embodiments. As shown, the transmission line termination circuit 100C is similar to the transmission line termination circuit 100A, except that the transmission line termination circuit 100C includes a tunable-resistance memory cell 120B instead of a resistor 60. The tunable-resistance memory cell 120B is programmable, and its resistance can be adjusted to provide more than two resistance values (i.e., at least three different resistance values, thereby making the tunable-resistance memory cell 120B distinguishable from a memory cell that can be programmed to either of only two states (e.g., high resistance and low resistance)). The tunable-resistance memory cell 120B can be coupled to circuitry 122, which can be coupled to a controller 125. The circuitry 122 may comprise, for example, one or more of wiring, a voltage source, a current source, and/or any other component that allows the state (resistance) of the tunable-resistance memory cell 120B to be set or changed. The controller 125 is configured use the circuitry 122 to set the resistance of the tunable-resistance memory cell 120B (e.g., to a target resistance value, as described further below).

To avoid the resistance of the tunable-resistance memory cell 120B being set or modified by ordinary signals being sent over the transmission line 40, the tunable-resistance memory cell 120B may be selected so that changing its state (writing to the memory cell 120B) requires a write current that is higher than the maximum current for typical signals on the transmission line 40.

The adjustable-resistance memory cell 120B can be, for example, a multilevel cell (MLC). The adjustable-resistance memory cell 120B can include the same kinds of materials as described above for the switching material 216 of the threshold switching device 105. For example, the tunable-resistance memory cell 120B can be a phase-change memory (PCM). A PCM leverages the ability of phase-change materials (such as Ge₂Sb₂Te₅, GST) to exist in multiple distinct resistance states. By controlling the heating and cooling processes, intermediate states between the fully amorphous (high resistance) and fully crystalline (low resistance) phases can be achieved to provide a target resistance to terminate the transmission line 40. The controller 125 can direct the circuitry 122 to cause a series of electrical pulses with varying amplitudes and durations to be applied to the tunable-resistance memory cell 120B to set the material to different phases, resulting in multiple resistance states.

As another example, the tunable-resistance memory cell 120B can be a resistive random access memory (ReRAM). ReRAM uses materials such as metal oxides (e.g., HfO₂, TiO₂) that can switch between different resistance states based on the formation and rupture of conductive filaments. By controlling the voltage and current applied, multiple stable resistance levels can be achieved to provide a target resistance to terminate the transmission line 40. The controller 125 can direct the circuitry 122 to cause controlled voltage and/or current pulses to be applied to form or dissolve conductive filaments to achieve different resistance states.

Although PCM and ReRAM have been provided as examples of suitable memory cells for the tunable-resistance memory cell 120B, it is to be appreciated that, in general, any memory cell with an adjustable resistance could be used in the example of FIG. 6A.

In the example circuit of FIG. 6A, the termination impedance is provided by the tunable-resistance memory cell 120B, which can, at least in theory, provide any resistance between a minimum value and maximum value. There may be situations, however, in which it is desirable or convenient to use two-state memory cells (memory cells that have two resistance states) rather than a tunable-resistance memory cell 120B. An example of a two-state memory cell is an MRAM cell.

Accordingly, as an alternative to the tunable-resistance memory cell 120B, a termination circuit can use two-state memory cells that have binary resistance values (e.g., either approximately a first resistance or approximately a second resistance, but no other resistance values) in a configuration that allows the overall termination resistance to be set and/or adjusted. Specifically, a plurality of two-state memory cells can be connected in parallel to provide flexibility in the overall resistance value (e.g., to approximate to a desired degree the flexibility that can be provided by the tunable-resistance memory cell 120B). The various two-state memory cells can be substantially identical to each other (e.g., all two-state memory cells can provide resistances R1 and R2), or they can offer different resistance options (e.g., one two-state memory cell can provide resistances R1 and R2, another two-state memory cell can provide resistances R3 and R4, etc.). It will be appreciated that many possibilities for resistance options exist and are within the scope of the disclosures herein.

Thus, in some embodiments, the termination impedance is provided by a resistive network comprising non-volatile two-state memory cells whose resistance states can be individually controlled such that the resistive network, once programmed, can provide different overall resistance values as the termination impedance. FIG. 6B is an example of a transmission line termination circuit 100D for terminating the transmission line 40 in accordance with some embodiments. The transmission line termination circuit 100D is similar to the transmission line termination circuit 100C shown in FIG. 6A, except that the tunable-resistance memory cell 120B has been replaced by a resistive network 140 (described further below in the context of FIG. 6C).

In the example of FIG. 6B, the resistive network 140 is coupled to circuitry 145, which is coupled to a controller 125. The circuitry 145 may comprise, for example, one or more of wiring, a voltage source, a current source, and/or any other component that allows the elements of the resistive network 140 to be programmed to control the overall resistance of the resistive network 140. The controller 125 is configured use the circuitry 145 to control the configuration of some or all of the resistive elements in the resistive network 140.

FIG. 6C illustrates an example of a resistive network 140 in accordance with some embodiments. In the example shown in FIG. 6C, the resistive network 140 includes a plurality of resistive elements, namely, two-state memory cells, in a parallel arrangement. Specifically, a two-state memory cell 130A, a two-state memory cell 130B, a two-state memory cell 130C, and a two-state memory cell 130N are connected in parallel. It is to be appreciated that there is no particular significance to the letter “N” being used for the last of the two-state memory cells 130. In general, there can be as few as a single two-state memory cell 130. Additionally, as indicated by the ellipses, there can be additional two-state memory cells 130 in the resistive network 140. Generally speaking, the resistive network 140 can include any number of two-state memory cells 130.

It will be appreciated that the resistance of the resistive network 140 can be adjusted by setting various of its two-state memory cells 130 to one of their two available resistance states in order to achieve a desired resistance. Each of the two-state memory cells 130 in the resistive network 140 can be individually controllable and can be set to either of its resistance states independently of the rest of the two-state memory cells 130. Thus, at least one (and up to all) of the two-state memory cells 130 is coupled to the circuitry 145 such that the overall resistance of the resistive network 140 can be adjusted by the controller 125. It will be appreciated that with proper selections of the number of two-state memory cells 130 and their available resistance states (the resistances the two-state memory cells 130 can provide), the resistive network 140 can provide flexibility similar to, but potentially more quantized than, the tunable-resistance memory cell 120B of FIG. 6A. The number of two-state memory cells 130 and the overall resistance of the resistive network 140 can be designed to be able to provide a suite of resistance values that can be computed using the well-known reciprocal sum formula for parallel resistors.

Although FIG. 6C shows only one parallel configuration of two-state memory cells 130, it is to be appreciated that if the maximum possible resistance that can be provided by a single resistive network 140 is lower than the termination resistance needed for a particular application (e.g., to terminate a particular node of the transmission line 40), multiple resistive networks 140 can be connected in series. The memory cell networks 140 connected in series can be identical, or they can be different. They can be controlled by the same or different circuitry 145 and the same or different controllers 125. It will be appreciated by those having ordinary skill in the art that there are many configurations that can be used to accomplish the programmability and flexibility described herein, and the examples provided are not intended to be limiting.

### Selective Termination with Programmable Termination Impedance

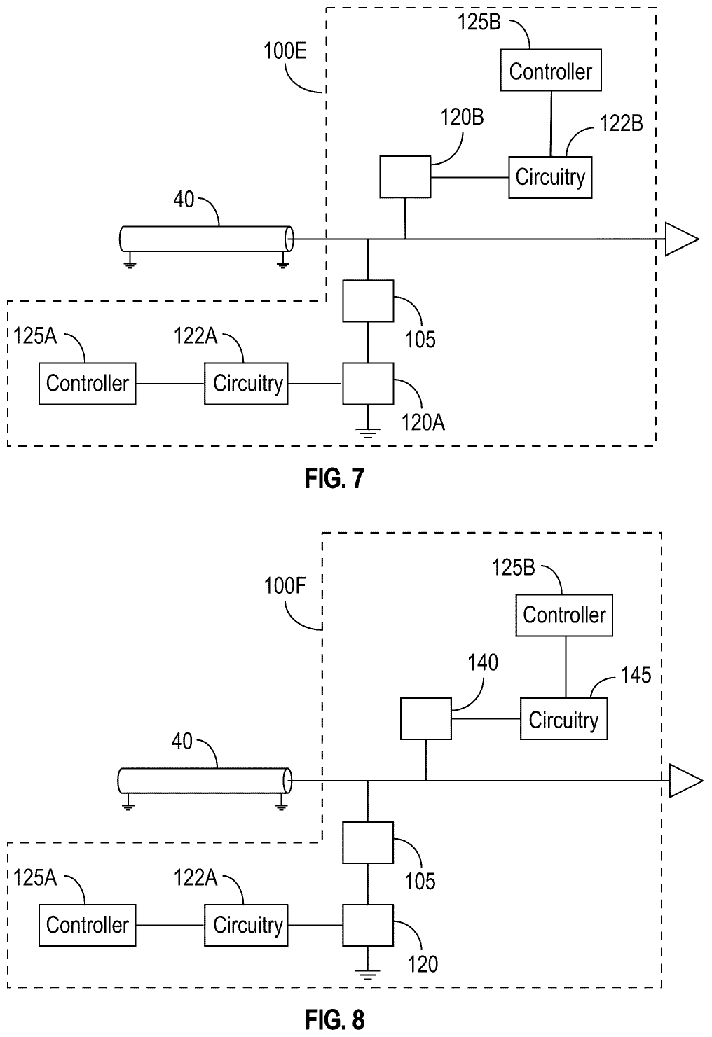

The techniques described and illustrated in the contexts of FIGS. 5 and 6A can be combined. FIG. 7 is an example of a transmission line termination circuit 100E in accordance with some embodiments. The transmission line termination circuit 100E includes a threshold switching device 105, a memory cell 120A, circuitry 122A coupled to the memory cell 120A, and a controller 125A coupled to the circuitry 122A. These components are situated and operate as described above in the discussion of FIG. 5. That discussion applies here and is not repeated.

The termination impedance in FIG. 7 is provided by a tunable-resistance memory cell 120B, which is coupled to circuitry 122B and a controller 125B, which are situated and operate as described above in the discussion of FIG. 6A. That discussion applies here and is not repeated. The controller 125A and controller 125B can be separate, or they can be combined. Similarly, some or all of the circuitry 122A and the circuitry 122B can be separate, or some or all of it can be shared/combined.

The techniques described and illustrated in the contexts of FIG. 5 and FIG. 6B can also be combined. FIG. 8 is an example of a transmission line termination circuit 100F in accordance with some embodiments. The transmission line termination circuit 100F includes a threshold switching device 105, a memory cell 120A, circuitry 122A coupled to the memory cell 120A, and a controller 125A coupled to the circuitry 122A. These components are situated and operate as described above in the discussion of FIG. 5. That discussion applies here and is not repeated.

The termination impedance in FIG. 8 is provided by a resistive network 140, which is coupled to circuitry 145 and a controller 125B. The resistive network 140, circuitry 145, and controller 125B are situated and operate as described above in the contexts of FIGS. 6B and 6C. The controller 125A and controller 125B can be separate, or they can be combined. Similarly, some or all of the circuitry 122A and the circuitry 145 can be separate, or it can be shared/combined.

### Programmable Termination Resistance with Diode Switching

As explained above in the contexts of FIGS. 6B, 6C, 7, and 8, the resistor 60 shown in several of the drawings herein can be replaced by a tunable-resistance memory cell 120B or a resistive network 140 (e.g., comprising one two-state memory cell 130 or a plurality of two-state memory cells 130 in a parallel configuration).

Although, as explained above, the use of a threshold switching device 105 can offer substantial advantages over the first diode 55A and second diode 55B used in the circuit 50 shown in FIG. 2, the adjustable/programmable termination impedance techniques described in the context of FIGS. 6A, 6B, and 6C can be used with the first diode 55A and second diode 55B shown in FIG. 2.

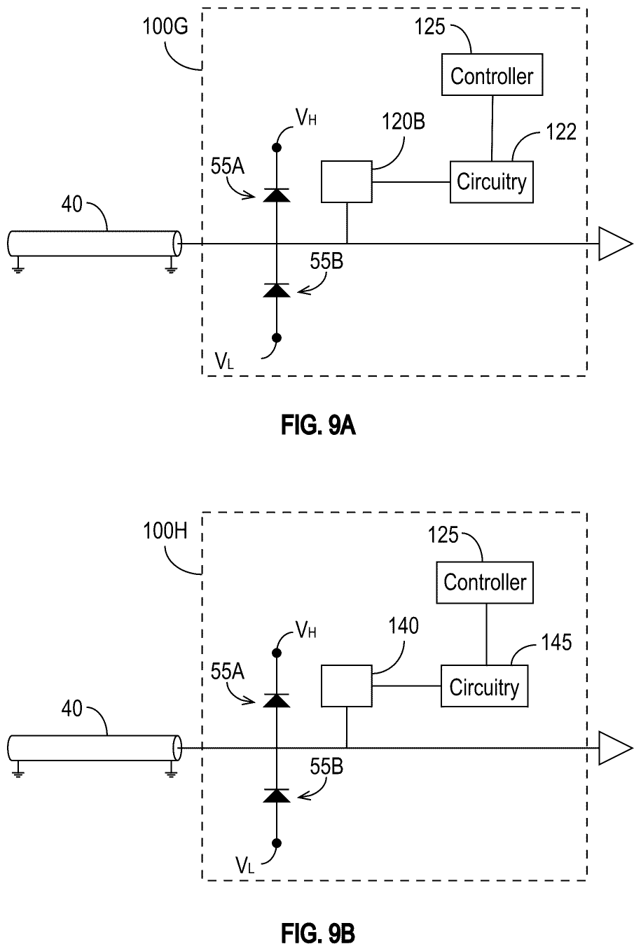

FIG. 9A is an example of a transmission line termination circuit 100G that uses diodes and an adjustable/programmable termination impedance in accordance with some embodiments. The transmission line termination circuit 100G includes the first diode 55A and second diode 55B configured as described above for FIG. 2. In the transmission line termination circuit 100G, the resistor 60 in FIG. 2 has been replaced by the tunable-resistance memory cell 120B, circuitry 122, and controller 125 first shown and described in the context of FIG. 6A. Those descriptions apply to FIG. 9A and are not repeated here.

FIG. 9B is an example of a transmission line termination circuit 100H that uses diodes and an adjustable/programmable termination impedance in accordance with some embodiments. The transmission line termination circuit 100H includes the first diode 55A and second diode 55B configured as described above for FIG. 2. In the transmission line termination circuit 100H, the resistor 60 in FIG. 2 has been replaced by the resistive network 140, circuitry 145, and controller 125 first shown and described in the context of FIGS. 6B and 6C. Those descriptions apply to FIG. 9B and are not repeated here.

### Setting and/or Optimizing Node Terminations and/or Termination Resistances

As explained above, although the concept of terminating a transmission line is simple in theory, it can be difficult in practice to determine an optimal or even workable termination strategy for a network that has multiple nodes, especially when the network has a complex configuration. For example, with reference to FIG. 1D, it is not apparent which of the node 15A, node 15B, node 15C, node 15D, and node 15E should be terminated and which should not. The transmission line termination circuit 100A, transmission line termination circuit 100B, transmission line termination circuit 100C, transmission line termination circuit 100D, transmission line termination circuit 100E, transmission line termination circuit 100F, transmission line termination circuit 100G, and/or transmission line termination circuit 100H described above can be leveraged to control and/or change node termination settings.

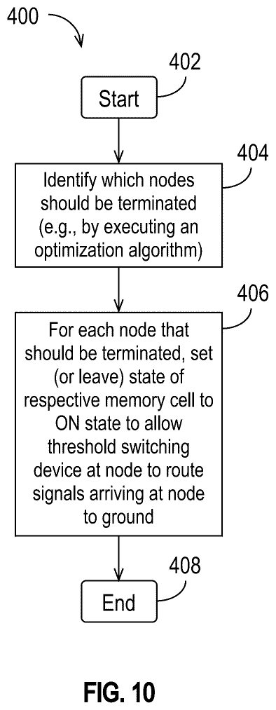

FIG. 10 is a flow diagram illustrating a method 400 of selectively terminating nodes of a transmission line using in accordance with some embodiments. Each of the nodes is coupled to a respective termination circuit, such as the transmission line termination circuit 100B, the transmission line termination circuit 100E, or the transmission line termination circuit 100F. Thus, each respective transmission circuit comprises a respective threshold switching device 105 and to a respective memory cell 120A that allows control of whether the node is terminated or non-terminated.

The respective memory cell 120A for a node can be programmed (or set) individually to be in an ON state or an OFF state. In the ON state, the respective memory cell 120A allows the respective threshold switching device 105 to route signals arriving at the respective node from (the first conductor of) the transmission line 40 to ground (the second conductor of the transmission line 40). In the OFF state, the respective memory cell 120A reduces current shunted by the respective threshold switching device 105 to ground (the second conductor of the transmission line 40).

At block 402 of FIG. 10, the method 400 begins. At block 404, the nodes that should be terminated are identified in any suitable manner. For example, the nodes that should be terminated can be identified by executing an optimization algorithm, such as a derivative-free optimization algorithm (e.g., Nelder-Mead method, a Bayesian optimization, a direct search method, a Hooke-Jeeves algorithm, Powell's method, simulated annealing, etc.).

At block 406, for each node identified in block 404 as a node that should be terminated, the state of the respective memory cell 120A is set to the ON state (or, depending on how block 404 is performed, left in the ON state) to allow the respective threshold switching device 105 at the node to route signals arriving at the node (via the first conductor of the transmission line 40) to ground (the second conductor of the transmission line 40) (thereby providing FPT functionality at the node). At block 408, the method 400 ends.

In some embodiments, identifying the nodes that should be terminated at block 404 comprises testing two or more possible (candidate) configurations and terminating nodes in accordance with the configuration that offers the best (or better/preferred, or adequate (e.g., meeting some requirement)) performance.

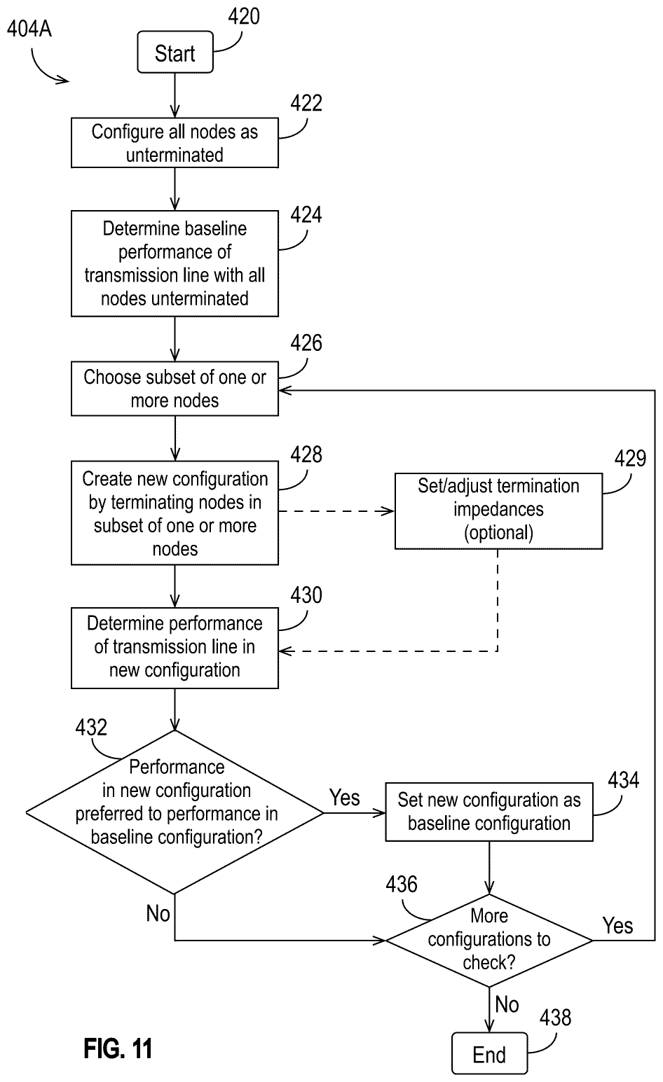

FIG. 11 is a flow diagram of an example of a process 404A that can be performed at block 404 of FIG. 10. At block 420, the process 404A begins. At block 422, all of the nodes are configured as unterminated. For example, each memory cell 120A is configured to be in the OFF state. At block 424, a baseline performance is determined while all of the nodes are unterminated. The performance can be determined using any suitable metric. For example, the metric could be a bit rate (e.g., achievable, average, maximum, etc.) over the transmission line 40.

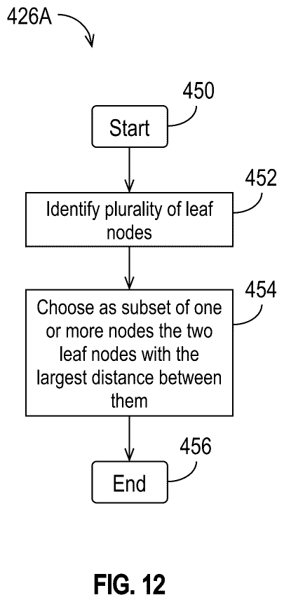

At block 426, a subset of one or more nodes is chosen. The subset can be chosen in any suitable way. FIG. 12, discussed below, is an example of one process to choose a subset of nodes.

At block 428, a new configuration is created by terminating the nodes in the subset of one or more nodes chosen at block 426. For example, for each node chosen in block 426, the state of the respective memory cell 120A is set to the ON state to allow the respective threshold switching device 105 at that node to route signals arriving at the node (via the first conductor of the transmission line 40) to ground (the second conductor of the transmission line 40). The rest of the nodes are left non-terminated. For example for each node not chosen in block 426, the state of the respective memory cell 120A is set to the OFF state to prevent the respective threshold switching device 105 at that node from routing signals arriving at the node (via the first conductor of the transmission line 40) to ground (the second conductor of the transmission line 40).

At block 430, the performance of the transmission line 40 with the new configuration is determined. The performance can be determined using any suitable metric. For example, the metric could be a bit rate (e.g., achievable, average, maximum, etc.) over the transmission line 40 while the nodes chosen in block 426 are terminated and the remaining nodes are unterminated.

At block 432, it is determined if the performance of the transmission line 40 with the terminations of the new configuration is preferable to the performance of the transmission line in the baseline configuration. For example, it might be determined at block 432 if the average or maximum bit rate over the transmission line 40 is higher in the new configuration than in the baseline configuration. If so, at block 434, the new configuration is set (saved or stored) as the baseline configuration, and the process 404A proceeds to block 436. If the performance of the transmission line 40 with the new termination configuration is not preferable to the performance of the transmission line in the baseline configuration, then no change is made to the baseline configuration, and the process 404A proceeds to block 436.

At block 436, it is determined whether there are additional configurations to check. This determination can be made, for example, by deciding whether the current preferred performance (i.e., the performance of the current baseline configuration, which might recently have changed) is sufficient. If the current preferred performance is sufficient (“no” path), then the current baseline configuration establishes which nodes are terminated at block 406 in FIG. 10, and the process 404A ends at block 438.

If, at block 436, it is determined that there are more configurations to check, the process 404A returns to block 426, where a new subset of one or more nodes is selected in any suitable manner. The new subset of one or more nodes is different from the last subset of one or more nodes that was checked. The new subset of one or more nodes can include any number of nodes (e.g., any one node, any two or more nodes, any three or more nodes, etc.). In some embodiments in which the process 426A (described below in the context of FIG. 12) was previously performed at block 426, the new subset of one or more nodes can include the two leaf nodes having the largest distance between them among the plurality of leaf nodes. In other words, the new subset of one or more nodes can be a superset of the nodes found at block 454 of the process 426A. In general, the new subset of one or more nodes can be a superset of any previously-chosen subset of one or more nodes, or it can be entirely different.

It will be appreciated that blocks 426 through 436 shown in FIG. 11 can be performed as many times as there are combinations of nodes that could be terminated.

FIG. 12 illustrates an example of a process 426A that can be performed at block 426 of FIG. 11 to choose the nodes to terminate in a configuration being tested. For example, the process 426A can be used the first time the block 426 in FIG. 11 is performed.

The process 426A begins at block 450. At block 452, a plurality of leaf nodes is identified. The leaf nodes are those nodes with only one connection to the transmission line 40. For example, with reference to FIG. 1D, the leaf nodes are node 15A, node 15D and node 15E.

With reference to FIG. 12, at block 454, the two leaf nodes with the largest distance between them are selected as the subset of one or more nodes. For the network 10C in FIG. 1D, the two leaf nodes with the largest distance between them are the node 15A and node 15E. Thus the node 15A and node 15E would be chosen as the subset of one or more nodes if the process 426A were applied to the network 10C in FIG. 1D. At block 456 of FIG. 12, the process 426A ends.

As explained above (e.g., in the discussion of FIGS. 6A, 6B, 7, and 8), in some embodiments, the termination impedance is adjustable/programmable.

Accordingly, the process 404A shown in FIG. 11 can include an optional step in which one or more termination impedances are adjusted (e.g., as described above in the contexts of FIGS. 6A-6C, 7, 8, 9A, and 9B). Specifically, after the block 428, at block 429, some or all of the termination impedances of the subset of one or more nodes chosen at block 426 can be set or adjusted (e.g., as described above for the tunable-resistance memory cell 120B and/or the resistive network 140). In some embodiments, setting or adjusting the termination impedances at block 429 comprises executing an optimization algorithm to determine a termination impedance value of at least one node. In some embodiments, the optimization algorithm comprises a derivative-free optimization algorithm (e.g., a Nelder-Mead method, a Bayesian optimization, a direct search method, a Hooke-Jeeves algorithm, Powell's method, simulated annealing).

In the foregoing description and in the accompanying drawings, specific terminology has been set forth to provide a thorough understanding of the disclosed embodiments. In some instances, the terminology or drawings may imply specific details that are not required to practice the invention.

To avoid obscuring the present disclosure unnecessarily, well-known components are shown in block diagram form and/or are not discussed in detail or, in some cases, at all.

Unless otherwise specifically defined herein, all terms are to be given their broadest possible interpretation, including meanings implied from the specification and drawings and meanings understood by those skilled in the art and/or as defined in dictionaries, treatises, etc. As set forth explicitly herein, some terms may not comport with their ordinary or customary meanings.

As used in the specification and the appended claims, the singular forms “a,” “an” and “the” do not exclude plural referents unless otherwise specified. The word “or” is to be interpreted as inclusive unless otherwise specified. Thus, the phrase “A or B” is to be interpreted as meaning all of the following: “both A and B,” “A but not B,” and “B but not A.” Any use of “and/or” herein does not mean that the word “or” alone connotes exclusivity.

As used in the specification and the appended claims, phrases of the form “at least one of A, B, and C,” “at least one of A, B, or C,” “one or more of A, B, or C,” and “one or more of A, B, and C” are interchangeable, and each encompasses all of the following meanings: “A only,” “B only,” “C only,” “A and B but not C,” “A and C but not B,” “B and C but not A,” and “all of A, B, and C.”

To the extent that the terms “include(s),” “having,” “has,” “with,” and variants thereof are used in the detailed description or the claims, such terms are intended to be inclusive in a manner similar to the term “comprising,” i.e., meaning “including but not limited to.”

The terms “exemplary” and “embodiment” are used to express examples, not preferences or requirements.

The term “coupled” is used herein to express a direct connection/attachment as well as a connection/attachment through one or more intervening elements or structures.

The terms “over,” “under,” “between,” and “on” are used herein refer to a relative position of one feature with respect to other features. For example, one feature disposed “over” or “under” another feature may be directly in contact with the other feature or may have intervening material. Moreover, one feature disposed “between” two features may be directly in contact with the two features or may have one or more intervening features or materials. In contrast, a first feature “on” a second feature is in contact with that second feature.

The term “substantially” is used to describe a structure, configuration, dimension, etc. that is largely or nearly as stated, but, due to manufacturing tolerances and the like, may in practice result in a situation in which the structure, configuration, dimension, etc. is not always or necessarily precisely as stated. For example, describing two lengths as “substantially equal” means that the two lengths are the same for all practical purposes, but they may not (and need not) be precisely equal at sufficiently small scales. As another example, a structure that is “substantially vertical” would be considered to be vertical for all practical purposes, even if it is not precisely at 90 degrees relative to horizontal.

The drawings are not necessarily to scale, and the dimensions, shapes, and sizes of the features may differ substantially from how they are depicted in the drawings.

Although specific embodiments have been disclosed, it will be evident that various modifications and changes may be made thereto without departing from the broader spirit and scope of the disclosure. For example, features or aspects of any of the embodiments may be applied, at least where practicable, in combination with any other of the embodiments or in place of counterpart features or aspects thereof.

Accordingly, the specification and drawings are to be regarded in an illustrative rather than a restrictive sense. Without prejudice, and without surrender of any subject matter, please amend the claims as follows:

1. A transmission line termination circuit for terminating a transmission line, the transmission line termination circuit comprising:
a threshold switching device, comprising:
a first terminal to be coupled to a first conductor of the transmission line,
a second terminal to be coupled to a second conductor of the transmission line, and
an active layer situated between the first terminal and the second terminal, wherein the active layer comprises a switching material, wherein the switching material is configured to be in a substantially conductive state in response to a voltage on the transmission line being in a range above a threshold voltage and in a substantially non-conductive state in response to the voltage on the transmission line being in a range below the threshold voltage.

2. The transmission line termination circuit recited in claim 1, wherein the switching material comprises a chalcogenide.

3. The transmission line termination circuit recited in claim 2, wherein the threshold switching device comprises an Ovonic threshold switching (OTS) switch.

4. The transmission line termination circuit recited in claim 1, wherein the switching material comprises a transition metal oxide, and wherein the substantially conductive state is a metallic state, and the substantially non-conductive state is an insulating state.

5. The transmission line termination circuit recited in claim 4, wherein the transition metal oxide comprises niobium dioxide (NbO₂) or chromium-doped vanadium sesquioxide (V₂O₃:Cr).

6. The transmission line termination circuit recited in claim 1, wherein the threshold switching device is bipolar.

7. The transmission line termination circuit recited in claim 1, further comprising a termination impedance, wherein the termination impedance comprises a resistance.

8. The transmission line termination circuit recited in claim 7, wherein the resistance is inherent to the threshold switching device.

9. The transmission line termination circuit recited in claim 1, further comprising:
a memory cell situated between and coupled to the second terminal of the threshold switching device and the second conductor of the transmission line, wherein the memory cell is characterized by an ON state in which the memory cell is configured to allow the threshold switching device to shunt current from the first conductor of the transmission line to the second conductor of the transmission line, and an OFF state in which the memory cell is configured to reduce a current shunted to the second conductor of the transmission line through the threshold switching device.

10-11. (canceled)

12. The transmission line termination circuit recited in claim 9, further comprising:
circuitry coupled to the memory cell to allow a state of the memory cell to be set to the ON state or to the OFF state; and
a controller coupled to the circuitry and configured to set the state of the memory cell using the circuitry.

13. (canceled)

14. The transmission line termination circuit recited in claim 9, further comprising a termination impedance, wherein the termination impedance comprises a resistance.

15. The transmission line termination circuit recited in claim 14, wherein the resistance is inherent to at least one of the threshold switching device or the memory cell.

16. The transmission line termination circuit recited in claim 1, further comprising a termination impedance, wherein the termination impedance comprises a memory cell.

17. The transmission line termination circuit recited in claim 16, wherein a resistance of the memory cell is adjustable.

18-19. (canceled)

20. The transmission line termination circuit recited in claim 17, further comprising
circuitry coupled to the memory cell to allow the resistance of the memory cell to be set; and
a controller coupled to the circuitry and configured to set the resistance of the memory cell using the circuitry.

21. The transmission line termination circuit recited in claim 1, further comprising a termination impedance, wherein the termination impedance comprises a resistive network.

22. The transmission line termination circuit recited in claim 21, wherein the resistive network comprises a plurality of memory cells in a parallel arrangement, and further comprising:
circuitry coupled to each memory cell of the plurality of memory cells; and
a controller coupled to the circuitry and configured to use the circuitry to configure the resistive network to provide a target resistance.

23. The transmission line termination circuit recited in claim 22, wherein the plurality of memory cells comprises a plurality of two-state memory cells, wherein at least one two-state memory cell of the plurality of two-state memory cells is configured to be in a first resistance state or a second resistance state depending on an applied voltage, and wherein the controller is configured to control whether the at least one of the plurality of two-state memory cells is in the first resistance state or the second resistance state.

24-25. (canceled)

26. The transmission line termination circuit recited in claim 1, further comprising:
a first memory cell situated between and coupled to the second terminal of the threshold switching device and the second conductor of the transmission line, wherein the first memory cell is characterized by an ON state in which the first memory cell is configured to allow the threshold switching device to shunt current from the first conductor of the transmission line to the second conductor of the transmission line, and an OFF state in which the first memory cell is configured to reduce the current shunted to the second conductor of the transmission line from the first conductor of the transmission line through the threshold switching device;
first circuitry coupled to the first memory cell to allow a state of the first memory cell to be set to the ON state or to the OFF state; and
a first controller coupled to the first circuitry and configured to set the state of the first memory cell using the first circuitry.

27. The transmission line termination circuit recited in claim 26, further comprising a termination impedance, wherein the termination impedance comprises a second memory cell.

28. The transmission line termination circuit recited in claim 27, wherein a resistance of the second memory cell is adjustable.

29-33. (canceled)

34. The transmission line termination circuit recited in claim 26, further comprising a termination impedance, wherein the termination impedance comprises a resistive network.

35. The transmission line termination circuit recited in claim 34, wherein the resistive network comprises a plurality of additional memory cells in a parallel arrangement, and further comprising:
second circuitry coupled to each memory cell of the plurality of additional memory cells; and
a second controller coupled to the second circuitry and configured to use the second circuitry to configure the resistive network to provide a particular resistance.

36. The transmission line termination circuit recited in claim 35, wherein the plurality of additional memory cells comprises a plurality of two-state memory cells, wherein at least one two-state memory cell of the plurality of two-state memory cells is configured to be in a first resistance state or a second resistance state depending on an applied voltage, and wherein the second controller is configured to control whether the at least one of the plurality of two-state memory cells is in the first resistance state or the second resistance state.

37-42. (canceled)

43. A transmission line termination circuit for terminating a transmission line, the transmission line termination circuit comprising:
a first diode configured to be coupled to a first voltage source;
a second diode configured to be coupled to a second voltage source, wherein an anode of the first diode is coupled to a cathode of the second diode;
a tunable-resistance element coupled to the anode of the first diode and to the cathode of the second diode;
circuitry coupled to the tunable-resistance element to allow a resistance of the tunable-resistance element to be set; and
a controller coupled to the circuitry and configured to set the resistance of the tunable-resistance element using the circuitry.

44. The transmission line termination circuit recited in claim 43, wherein the tunable-resistance element comprises a memory cell.

45. The transmission line termination circuit recited in claim 44, wherein a resistance of the memory cell is programmable to at least three resistance values.

46-47. (canceled)

48. The transmission line termination circuit recited in claim 43, wherein the tunable-resistance element comprises a resistive network.

49. The transmission line termination circuit recited in claim 48, wherein the resistive network comprises a plurality of memory cells in a parallel arrangement, and wherein the controller is configured to use the circuitry to configure the resistive network to provide a target resistance.

50. The transmission line termination circuit recited in claim 49, wherein the plurality of memory cells comprises a plurality of two-state memory cells, wherein at least one two-state memory cell of the plurality of two-state memory cells is configured to be in a first resistance state or a second resistance state depending on an applied voltage, and wherein the controller is configured to control whether the at least one two-state memory cell of the plurality of two-state memory cells is in the first resistance state or the second resistance state.

51-70. (canceled)
